(19) United States
(12) Patent Application Publication
(10) Pub. No.: US 2008/0012038 A1
(43) Pub. Date: Jan. 17, 2008

(54) Blue-light emitting aluminum nitride material and method of manufacturing the same

(75) Inventors: Naomi Teratani, Nagoya-shi (JP); Naohito Yamada, Kasugai-shi (JP)

Correspondence Address: BURR & BROWN, PO BOX 7068, SYRACUSE, NY, 13261-7068, US

(73) Assignee: NGK Insulators, Ltd., Nagoya-Shi (JP)

(21) Appl. No.: 11/827,104

(22) Filed: Jul. 10, 2007

(30) Foreign Application Priority Data
Jul. 11, 2006 (JP) 2006-190204
Jul. 4, 2007 (JP) 2007-176657

(51) Int. Cl. H01L 33/00; H01L 21/00

(52) U.S. Cl. 257/103; 257/E33.028; 438/46

(57) ABSTRACT

Carbon or a substance generating a carbon by thermal decomposition is added to prepared material containing aluminum nitride (AlN), an Si source such as silicon nitride (Si₃N₄) or a silicon oxide (SiO₂), and an Eu source such as europium oxide (Eu₂O₃) or europium nitrate or europium acetate, and the prepared material is reduced in a nitrogen atmosphere, and subsequently fired. SiO₂ is capable of converting into silicon nitride by reduction nitriding. Europium nitrate or europium acetate are capable of converting into Eu₂O₃ during a heat treatment process or converting into europium nitride (EuN) by reduction nitriding.

### CROSS REFERENCE TO RELATED APPLICATION

This application is based upon and claims the benefit of priority from a Japanese Patent Application No. TOKUGAN 2006-190204, filed on Jul. 11, 2006, and a Japanese Patent Application No. TOKUGAN 2007-176657, filed on Jul. 4, 2007; the entire contents of which are incorporated herein by reference.

### BACKGROUND OF THE INVENTION

1. Field of the Invention

The present invention relates to a blue-light emitting aluminum nitride material and a method of manufacturing the same.

2. Description of the Related Art

Aluminum nitride materials doped with a rare earth element or manganese, which are produced from metal aluminum and a rare earth compound or a manganese compound by a method called combustion synthesis, have been hitherto reported to emit visible light under UV or electron beam excitation. Among them, an aluminum nitride material doped with a rare earth element, thulium (Tm), is reported to emit blue light under electron beam excitation (K. Hara, H. Hikita, G. C. Lai, and T. Sakurai, 12th International Workshop on Inorganic and organic Electroluminescence & 2004 international Conference on the Science and Technology of Emissive Displays and Lighting (EL2004) Proceeding p. 24-27).

However, a thulium doped aluminum nitride phosphor is characterized in that the color of emitting light varies depending upon the type of excitation source. For example, the thulium doped aluminum nitride phosphor only emits light having a wavelength within infrared region when UV rays are used as an excitation source.

Meanwhile, when a flat panel display (FPD) is manufactured, a process of firing a phosphor onto a glass substrate in air is performed in general. For example, when a phosphor emitting blue light such as a barium magnesium aluminate (BAM) phosphor using in a plasma display panel (PDP) is fired on to a substrate by vaporizing an organic component, the luminescence intensity of the phosphor decreases. Thus, this phosphor has a problem that lacks stability in the high temperature air.

The present invention has been achieved to solve the above problems, and an object of the invention is to provide a blue-light emitting aluminum nitride material efficiently emitting blue light regardless of the type of excitation source and constituted of a stable and safe element and a method of manufacturing the same.

### SUMMARY OF THE INVENTION

As a result of intensive studies, the present inventors have found that a blue-light emitting aluminum nitride material efficiently emitting blue light regardless of the type of excitation source such as UV rays, electron beam or X-rays by adding carbon or a substance capable of generating a carbon by thermal decomposition to raw material containing aluminum nitride (AlN), an Si source such as silicon nitride (Si₃N₄) or silicon oxide (SiO₂), and an Eu source such as europium oxide (Eu₂O₃) or europium nitrate or europium acetate, and reducing the raw material in a nitrogen atmosphere, followed by firing it.

SiO₂ is capable of converting in to silicon nitride by reduction nitriding. Europium nitrate and europium acetate are capable of converting into Eu₂O₃ during a heat treatment process or converting into europium nitride (EuN) by reduction nitriding.

### BRIEF DESCRIPTION OF THE DRAWINGS

Exemplary embodiments of the invention will become more fully apparent from the following description and appended claims, taken in conjunction with the accompanying drawings. Understanding that these drawings depict only exemplary embodiments and are, therefore, not to be considered limiting of the invention's scope, the exemplary embodiments of the invention will be described with additional specificity and detail through use of the accompanying drawings in which:

FIG. 1 shows an X-ray diffraction profile of an aluminum nitride material of Example 1;

FIG. 2 shows a photoluminescence (PL) spectrum emitted from the aluminum nitride material of Example 1;

FIG. 3 shows an excitation spectrum at a maximum emission intensity of an aluminum nitride material of Example 11;

FIGS. 4A-4C show photographs of the aluminum nitride material of Example 1 taken by an Electron Probe (X-ray) Micro Analyzer (EPMA); and

FIG. 5 shows a cathode luminescence (CL) spectrum emitted from the aluminum nitride material of Example 1.

### DETAILED DESCRIPTION OF THE PREFERRED EMBODIMENTS

Preferred embodiments of the present invention will be explained below with reference to the accompanying drawings.

### Example 1

In Example 1, AlN, Si₃N₄, Eu₂O₃ and carbon (C) were first weighted so as to satisfy a weight ratio of 100, 2.33, 1.72 and 0.94 [wt %], respectively. Thereafter, these raw materials were wet-blended with isopropyl alcohol (IPA) used as a solvent. The obtained slurry was dried at 110[° C.] in nitrogen atmosphere. Note that the raw materials except for the carbon are mixed, dried and sieved, and thereafter, the carbon can be dry-blended in a mortar or the like.

Subsequently, the prepared material may be pressed using a die to provide a disk-shaped body (30 [φmm]). The shaped body was set in a crucible made of boron nitride (BN). The crucible was then placed in a vessel made of BN and fired in a furnace with a carbon heater to obtain a fired body. The prepared material can be put into the BN crucible directly. When putting the prepared material into the BN crucible directly, it is possible to suppress decreasing of the luminescence intensity by pulverization. Accordingly, an emitting material with particularly high luminescence intensity can be obtained.

The firing process was performed as follows. The shaped body was heated up to a reduction temperature at a rate of 1000[° C./h], and then kept at the reduction temperature for 10 hours or more. Thereafter it was heated up to a firing (maximum) temperature of 2000[° C.] at a rate of 300[° C./h], and kept at the firing (maximum) temperature for 4 hours, and cooled at a rate of 300[° C./h]. Note that the nitrogen pressure during reducing and firing processes was set at 0.8 [Mpa].

Finally, the fired body was pulverized in an alumina molar or the like to obtain an aluminum nitride material according to Example 1. Note that the carbon was added in an amount required for reducing the overall amount of oxygen contained in the raw material assuming that the amount of oxygen contained in aluminum nitride as an impurity is 1 [wt %], the amount of oxygen contained in the silicon nitride as an impurity is 2 [wt %]. More specifically, the amount of the carbon is calculated in accordance with the following reaction equations (1) to (3). Note that the carbon amount derived from the reaction equations corresponds to two-fold as large as that of reducible oxygen contained in the raw material in terms of molar amount.

(1) Al₂O₃+3C+N₂→2AlN+3CO (it is assumed that oxygen contained in AlN as an impurity is Al₂O₃)

(2) 3SiO₂+6C+2N₂→Si₃N₄+6CO (it is assumed that oxygen contained in Si₃N₄ as an impurity is SiO₂)

(3) EU₂O₃+3C+N₂→2EuN+3CO

Main object of adding carbon is to promote above reduction reaction. By promoting reduction reaction, generation of different crystalline phase including oxygen is inhibited and Si and Eu distribution in a state of solid solution within an aluminum nitride particle is promoted. Further, there is a possibility of controlling characteristics of aluminum nitride material by carbon distribution in a state of solid solution within an aluminum nitride particle.

Other object of adding carbon is to prevent aluminum nitride from sintering. When carbon is added to aluminum nitride, carbon reacts with oxygen as mentioned above, reducing the amount of oxygen required for sintering of aluminum nitride. In this manner, carbon inhibits a densification of aluminum nitride. Since an emitting material is often used as powder, it is desirable that it can pulverize easily after firing. In the aluminum nitride material produced by the method of the present invention, since sintering is inhibited by adding carbon, aluminum nitride particles are not tightly bound to each other. Therefore, when it is pulverized, the surface of the aluminum nitride particles are less damaged.

Thus, the aluminum nitride material can be easily pulverized and often remained a relatively smooth surface. As a result, an aluminum nitride light emitting material with high luminescence intensity can be obtained. When the aluminum nitride material was fired as pellet and when the aluminium nitride material of particle diameter smaller than that obtained by firing is required, the light emitting material itself is damaged by pulverization. The luminescence intensity of the pulverized aluminum nitride material decreases as compared to that of not being pulverized.

### Examples 2 to 8

In Examples 2 to 8, aluminum nitride materials according to Examples 2 to 8 were obtained in the same process as in Example 1, except that AlN, Si₃N₄, Eu₂O₃ and carbon (C) were weighted so as to satisfy a weight ratio of 100, 1.0 to 6.0, 0.1 to 4.4, and 0.46 to 1.6 [wt %], respectively, and that a firing temperature was set at 1800 to 2100[° C.]. Note that the addition amount of carbon was set assuming that oxygen contained in the raw material reacts with carbon to produce carbon monoxide and so as to correspond to not less than an equimolar amount to reducible oxygen at that time.

### Comparative Examples 1 to 3

In Comparative Examples 1 to 3, aluminum nitride materials according to Comparative Examples 1 to 3 were obtained in the same process as in Example 1, except that AlN, Si₃N₄, Eu₂O₃ and carbon (C) were weighted so as to satisfy a weight ratio of 100, 0, 0 to 2.16, and 0 to 2.00 [wt %], respectively, and that a firing temperature was set at 1800 to 2100[° C.]

### Comparative Example 4

In Comparative Example 4, aluminum nitride materials according to Comparative Example 4 was obtained in the same process as in Example 1, except that AlN, Si₃N₄, Eu₂O₃ and carbon (C) were weighted so as to satisfy a weight ratio of 100, 0, 22.85 and 0 [wt %], respectively, and that the firing process was performed by heated up to a firing (maximum) temperature of 1600[° C.] at a rate of 1000[° C./h], and kept at the firing (maximum) temperature for 4 hours, and cooled at a rate of 300[° C./h]. Note that the nitrogen pressure during firing processes was set at 0.15 [Mpa].

### Example 9

In Example 9, an aluminum nitride material according to Example 9 was obtained in the same process as in Example 1, except that AlN, Si₃N₄, Eu₂O₃ and carbon (C) were weighted so as to satisfy a weight ratio of 100, 2.77, 1.2 and 0.45 [wt %], respectively and except that the prepared material was directly put into BN crucible. In Example 9, since luminescence intensity is prevented from being decreased by pulverization, the aluminum nitride material exhibited particularly strong luminescence intensity and its average particle diameter was 5 [μm].

### Example 10

In Example 10, an aluminum nitride material according to Example 10 was obtained by subjecting the blue-light emitting aluminum nitride material obtained in Example 9 to a heat treatment performed at 2000[° C.] in a nitrogen atmosphere of 0.8 [MPa]. Since the heat treatment as shown in Table 2 was performed, luminescence intensity was improved and the average particle diameter was 6 [μm], which was larger than that of Example 9, to which no heat treatment was applied.

### Example 11

In Example 11, an aluminum nitride material according to Example 11 was obtained in the same process as in Example 1, except that AlN, Si₃N₄, Eu₂O₃ and carbon (C) were weighted so as to satisfy a weight ratio of 100, 2.77, 1.2 and 0.44 [wt %], respectively.

### Examples 12 to 16

In Examples 12 to 16, aluminum nitride materials according to Examples 12 to 16 were obtained by subjecting the blue-light emitting aluminum nitride material obtained in Example 11 to a heat treatment performed under the conditions shown in Table 2. Example 11 comprises a step of pulverizing pellets obtained after firing. The aluminum nitride material had an average particle diameter of 2 [μm]. When the material whose luminescence intensity was decreased by pulverization was subjected to a heat treatment in air and an inert gas atmosphere, the luminescence intensity was improved. As the inert gas atmosphere used argon, nitrogen and hydrogen can be mentioned. When the heat treatment was performed at 900[° C.] or less in air and 2100[° C.] or less in an inert gas atmosphere, the luminescence intensity was improved. For example, when the heat treatment was performed at 1500[° C.] or less in the nitrogen atmosphere, the luminescence intensity was improved without virtually changing the particle diameter. Furthermore, when the heat treatment was performed at a further higher temperature, the luminescence intensity was improved and the particle diameter increased. The average particle diameter was 4 [μm] when the heat treatment was performed at 2000[° C.]. As Example 11 is compared to Example 12, even if it performed heat treatment in air, luminescence intensity did not decrease, therefore it turned out that they are stable also in the high temperature air.

### [Evaluation of Crystalline Phase]

A crystalline phase of the aluminum nitride materials of Examples and Comparative Examples were determined by using a rotating-anode type X-ray diffractometer, “RINT” manufactured by “Rigaku Denki”, under the following conditions: CuKα, 50 [kV], 300 [mA], and 2θ=10-70 [°].

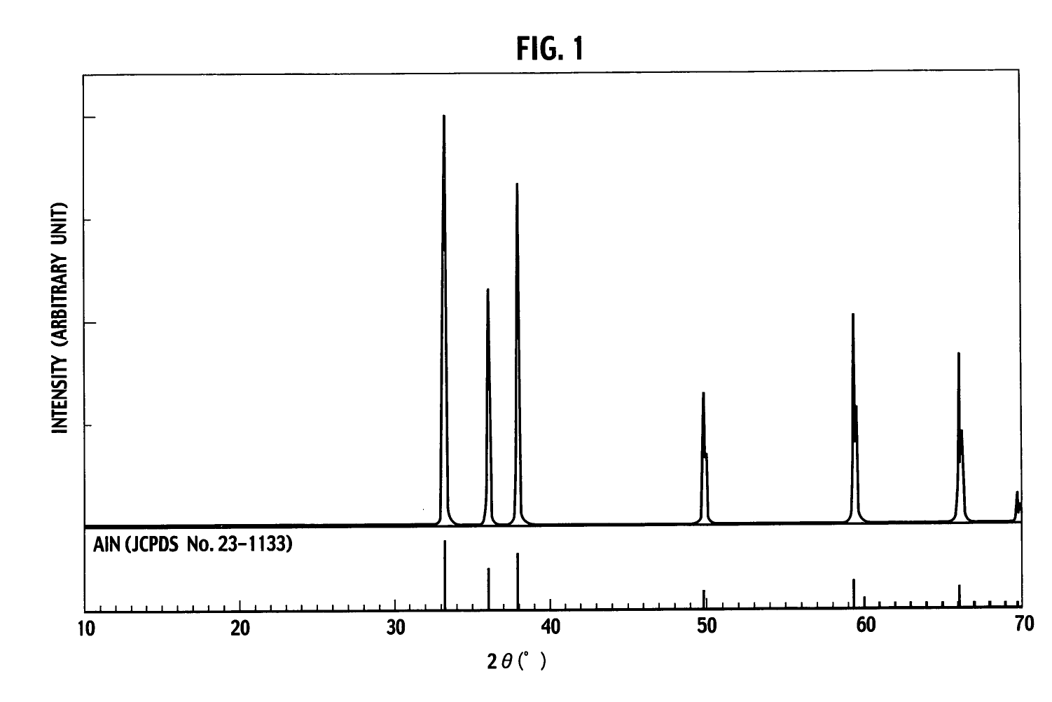

As a representative example, the X-ray diffraction profile of Example 1 is shown in FIG. 1 and the results of other Examples and Comparative Examples are shown in Tables 1, 2. It was confirmed that the aluminum nitride materials of Examples 1 to 16 are consist of aluminum nitride only; whereas those of Comparative Examples 2 to 4 contain a crystalline phase of a component other than aluminum nitride.

### [Evaluation of Lattice Parameter]

Lattice parameters were measured as follows. Specifically, from an XRD profile measured with the X-ray diffractometer, lattice parameter were calculated using a whole-powder-pattern fitting (WPPF) program.

First, Al₂O₃ powder of which lattice parameters were known was mixed as an internal standard with aluminum nitride materials of each example with a weight ratio of 1:1, and a CuKα ray from which a CuKβ ray was removed with a monochromater was applied to a sample, thus measuring a profile. The measurement was performed with a rotating-anode X-ray diffractometer of the “RINT-2000 series,” manufactured by “Rigaku Denki”, under the following conditions: 50 [kV], 300 [mA], and 2θ=30-120 [°].

Further, using a program, “WPPF,” which can be included as an option in this diffractometer, profile fitting was performed to derive lattice parameters. With “WPPF,” precise calculation can be performed if approximate values of lattice parameters of the internal standard and aluminum nitride are known.

In precise calculation, WPPF was started, and a fitting range 2θ was designated based on the measured profile. Subsequently, fitting was performed semi-automatically, and then manual fitting was performed. In the manual precise calculation, precise calculations were performed until a calculated profile coincides with the measured profile (Rwp (standard deviation)=not more than 0.1), by designating whether each of parameters, which are a background intensity, a peak intensity, lattice parameters, a half-value width, a peak asymmetry parameter, a low-angle profile intensity attenuation factor, and a high-angle profile intensity attenuation factor, is “fixed” or “variable”, for each calculation. By this precise calculation, highly reliable lattice parameters were obtained.

It should be noted that WPPF is described in detail in the following paper: H. Toraya, “Whole-Powder-Pattern Fitting Without Reference to a Structural Model: Application to X-ray Powder Diffractometer Data,” J. Appl. Cryst. 19, 440-447 (1986).

The results are shown in Tables 1, 2. It was found that the a-axis length of the lattice parameter each of the aluminum nitride materials of Examples is 3.1112 [A] or less.

### [Evaluation of Luminescence Property]

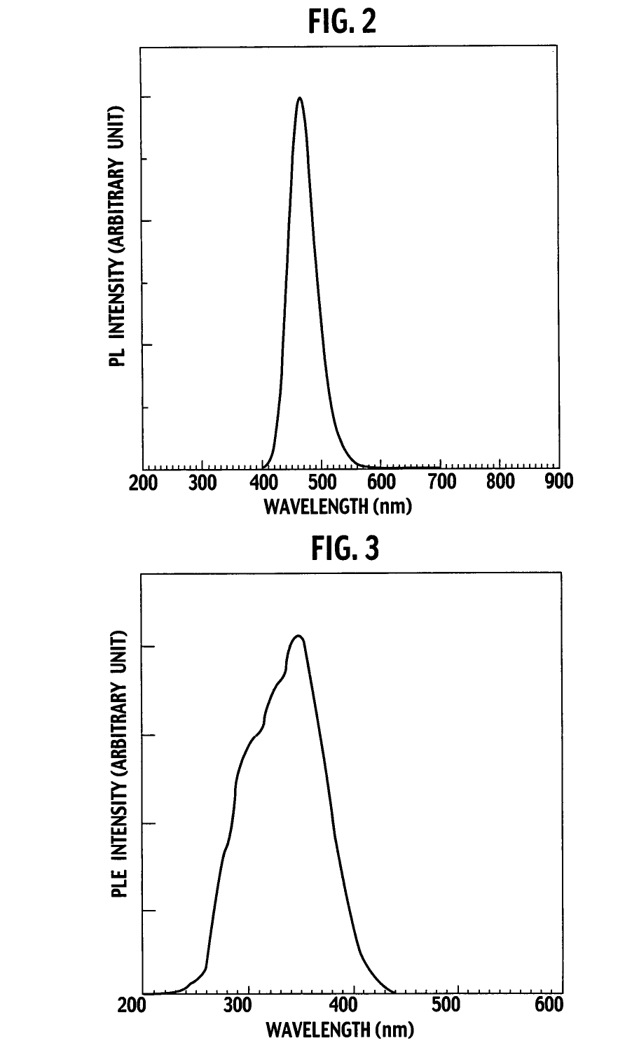

Luminescence properties of the aluminum nitride materials of Examples and Comparative Examples were obtained by a fluorescence spectrophotometer FP-6300 (JASCO). To describe more specifically, an aluminum nitride material was put into a holder. Excitation light having an arbitrary wavelength within the UV range was irradiated to the sample to obtain a photoluminescence (PL) spectrum. The excitation spectrum at a peak wavelength of the PL spectrum obtained was measured at the wavelength range of 220 to 430 [nm]. Furthermore, the light of the peak wavelength of the excitation spectrum was irradiated to obtain a PL spectrum within the wavelength range of 400 to 700 [nm]. In this way, the PL spectrum was obtained at an excitation wavelength giving a maximum intensity. FIG. 2 shows the PL spectrum of Example 1 at a maximum excitation wavelength, and Table 1 shows a maximum peak wavelength in the PL spectra of other Examples and Comparative Examples. Further, FIG. 3 shows an excitation spectrum according to Example 11 and Table 2 shows the wavelength of excitation light providing a maximum peak wavelength and a maximum intensity in each of the PL spectra according to Examples 9 to 16. As is apparent from FIG. 2, the aluminum nitride material of Example 1 emits blue light having a peak wavelength of 465 [nm]. Also in other examples, a light emission peak fell within the wavelength range of more than 450 [nm] to less than 500 [nm] as shown in Tables 1, 2. As is also apparent from FIG. 3, the wavelength of excitation light for the aluminum nitride material of Example 11 providing maximum luminescence intensity is 348 [nm]. In other Examples, excitation light having a wavelength within the range of more than 340 [nm] to less than 370 [nm] provided a maximum integrated luminescence intensity, as shown in Table 2. Subsequently, integrated luminescence intensity was calculated in accordance with the following method. The wavelength plotted on the transverse axis of a PL spectrum was converted into energy (converted based on 1 ev=1239.9 [nm]). The Gaussian function was fit to the PL spectrum to obtain the area of the PL spectrum. In this manner, the integrated luminescence intensity of the PL spectrum was derived. The integrated luminescence intensity derived from the PL spectra of Examples and Comparative Examples are shown in Tables 1, 2. It was confirmed that the aluminum nitride materials of Examples emit blue light having a large integrated luminescence intensity compared to the aluminum nitride materials of Comparative Examples.

### [Evaluation of Average Particle Diameter]

The aluminum nitride materials were embedded in an epoxy resin and polished the surface, which is observed by an electron microscope to determine particle diameter values at 30 particles in a visual field. The average of the 30 values is calculated.

### [Chemical Analysis Results]

The induction coupled plasma (ICP) emission spectrometry was performed to determine the amounts of silicon (Si) and europium (Eu) contained in aluminum nitride materials of Examples and Comparative Examples. The results are shown in Table 1. It was found that the aluminum nitride materials of Examples contain silicon in an amount of more than 0.5 [wt %] to less than 4 [wt %], and europium in an amount of more than 0.03 [wt %] to less than 0.8 [wt %].

### [EPMA Observation Results]

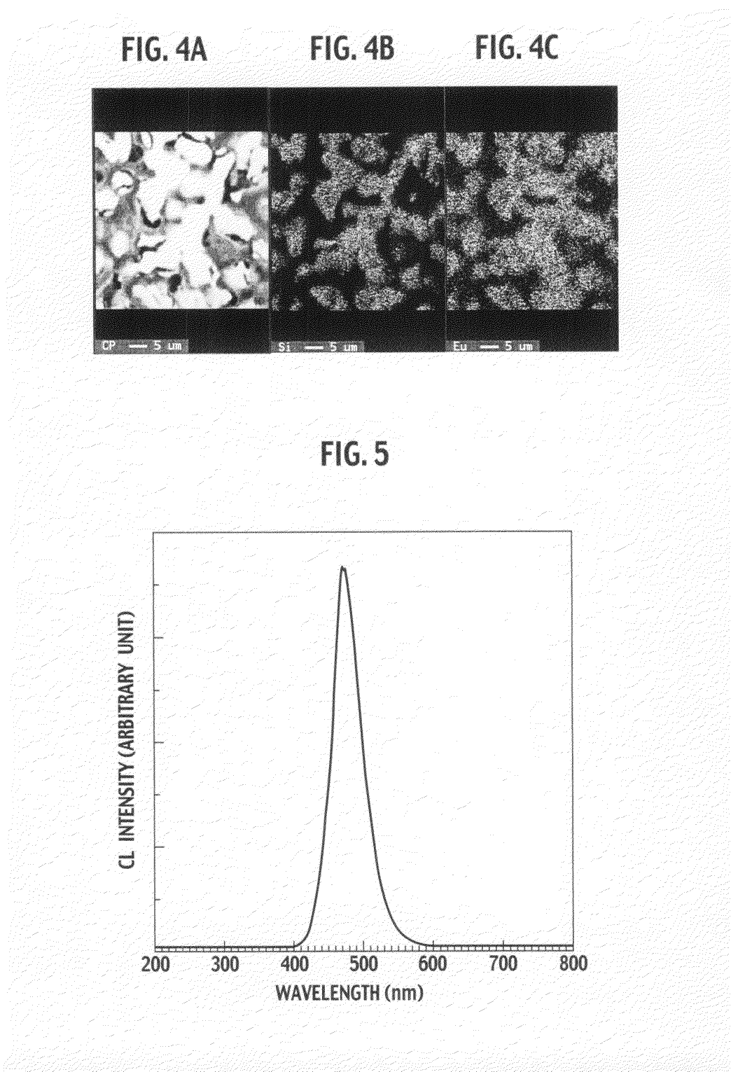

The aluminum nitride materials of Examples and Comparative Examples were embedded in an epoxy resin and polished the surface, the distribution of elements within a particle of each of the aluminum nitride materials was observed by an Electron Probe X-ray Micro Analyzer (EPMA). The observation results of Example 1 are shown in FIGS. 4A-4C as a representative example. FIG. 4A shows an SEM (Scanning Electron Microscopic) image of an observation site, FIG. 4B shows the distribution state of Si, and FIG. 4C shows the distribution state of Eu. It was demonstrated that Si and Eu are distributed uniformly in a state of solid solution within a particle of the aluminum nitride materials of Examples.

### [Evaluation of Cathode Luminescence Property]

With respect to the aluminum nitride materials of Examples and Comparative Examples, which were embedded in an epoxy resin and polished the surface, a cathode luminescence (CL) spectrum of an aluminum nitride particle was obtained by CL using a cathode luminescence equipment (MP-18M-S type, Jobin Ivon) attached to a scanning electron microscope (JSM-6300, JEOL Ltd). Note that measurement was performed in the conditions: acceleration voltage: 5 [kV] and irradiation current: 0.5 [nA]. FIG. 5 shows the CL spectrum of Example 1 as a representative example. In the aluminum nitride materials of Examples, it was confirmed that light is emitted from aluminum nitride particles, and that blue light having a peak at a wavelength of about 470 nm is also emitted under electron beam excitation.

TABLE 1

| | | | PROPERTIES OF FIRING BODY | | | |
|---|---|---|---|---|---|---|
| | | | CHEMICAL | | | |
| | FIRING CONDITION | | ANALYSIS VALUE | | | |
| | MAXIMUM | | Si | Eu | | |
| | TEMPERATURE | HOLDING | CONTENT | CONTENT | LENGTH OF | LENGTH OF |
| | (° C.) | TIME (h) | (wt %) | (wt %) | a-AXIS (Å) | c-AXIS (Å) |
| EXAMPLE 1 | 2000 | 4 | 1.39 | 0.55 | 3.10983 | 4.97752 |
| EXAMPLE 2 | 2100 | 4 | 1.18 | 0.22 | 3.11046 | 4.97948 |
| EXAMPLE 3 | 2100 | 4 | 1.12 | 0.14 | 3.11055 | 4.97962 |
| EXAMPLE 4 | 2100 | 4 | 1.92 | 0.26 | 3.11024 | 4.97895 |
| EXAMPLE 5 | 2100 | 4 | 1.15 | 0.23 | 3.11046 | 4.97948 |
| EXAMPLE 6 | 2100 | 4 | 2.94 | 0.74 | 3.10957 | 4.97742 |
| EXAMPLE 7 | 1800 | 4 | 1.01 | 0.21 | 3.11086 | 4.98060 |
| EXAMPLE 8 | 2100 | 4 | 1.16 | 0.04 | 3.11046 | 4.97935 |
| COMPARATIVE | 2100 | 4 | 0.06 | 0.02 | 3.11140 | 4.98028 |
| EXAMPLE 1 | | | | | | |
| COMPARATIVE | 2000 | 4 | 0.05 | 0.13* | 3.11139 | 4.98058 |
| EXAMPLE 2 | | | | | | |
| COMPARATIVE | 1800 | 4 | 0.08 | 1.2* | 3.11162 | 4.97926 |
| EXAMPLE 3 | | | | | | |
| COMPARATIVE | 1600 | 6 | 0.03 | 1.8* | 3.11151 | 4.98029 |
| EXAMPLE 4 | | | | | | |

| | PROPERTIES OF FIRING BODY | | | |
|---|---|---|---|---|
| | LATTICE | | LUMINESCENCE | PEAK |
| | VOLUME | CRYSTALLINE | INTEGRATED INTENSITY | WAVELENGTH |
| | (Å³) | PHASE | (ARBITRARY UNIT) | (nm) |
| EXAMPLE 1 | 41.68727 | AlN | 777 | 466 |
| EXAMPLE 2 | 41.72068 | AlN | 680 | 465 |
| EXAMPLE 3 | 41.72421 | AlN | 655 | 465 |
| EXAMPLE 4 | 41.71022 | AlN | 635 | 466 |
| EXAMPLE 5 | 41.71627 | AlN | 623 | 465 |
| EXAMPLE 6 | 41.67955 | AlN | 595 | 466 |
| EXAMPLE 7 | 41.73591 | AlN | 445 | 474 |
| EXAMPLE 8 | 41.71947 | AlN | 208 | 464 |
| COMPARATIVE | 41.75251 | AlN | 0 | — |
| EXAMPLE 1 | | | | |
| COMPARATIVE | 41.75490 | AlN, unknown | 0 | — |
| EXAMPLE 2 | | | | |
| COMPARATIVE | 41.74981 | AlN, EuAl₂0₄, | 29 | 520 |
| EXAMPLE 3 | | unknown | | |
| COMPARATIVE | 41.76146 | AlN, EuC₂ | 33.48 | 512 |
| EXAMPLE 4 | | | | |

*INCLUDING DIFFERENT CRYSTALLINE PHASE

TABLE 2

| | | | | | | PROPERTIES OF | |
|---|---|---|---|---|---|---|---|
| | FIRING | | | | | FIRING BODY | |
| | CONDITION | | HEAT TREATMENT CONDITION | | | LENGTH | LENGTH |
| | MAXIMUM | | MAXIMUM | | | OF | OF |
| | TEMPERATURE | HOLDING | TEMPERATURE | HOLDING | | a-AXIS | c-AXIS |
| | (° C.) | TIME (h) | (° C.) | TIME (h) | ATMOSPHERE | (Å) | (Å) |
| EXAMPLE 9 | 2000 | 4 | — | — | — | 3.10968 | 4.97785 |
| EXAMPLE 10 | 2000 | 4 | 2000 | 4 | N₂ | 3.10971 | 4.97765 |
| EXAMPLE 11 | 2000 | 4 | — | — | — | 3.10990 | 4.97756 |
| EXAMPLE 12 | 2000 | 4 | 700 | 1 | air | 3.10993 | 4.97755 |
| EXAMPLE 13 | 2000 | 4 | 700 | 1 | N₂ | 3.10994 | 4.97756 |
| EXAMPLE 14 | 2000 | 4 | 1300 | 1 | N₂ | 3.10991 | 4.97751 |
| EXAMPLE 15 | 2000 | 4 | 1500 | 1 | N₂ | 3.10991 | 4.97789 |
| EXAMPLE 16 | 2000 | 4 | 2000 | 4 | N₂ | 3.11031 | 4.97814 |

| | PROPERTIES OF FIRING BODY | | | | | |
|---|---|---|---|---|---|---|
| | | | LUMINESCENCE | | | |
| | | | INTEGRATED | | | AVERAGE |
| | LATTICE | | INTENSITY | PEAK | EXCITATION | PARTICLE |
| | VOLUME | CRYSTALLINE | (ARBITRARY | WAVELENGTH | WAVELENGTH | DIAMETER |
| | (Å³) | PHASE | UNIT) | (nm) | (nm) | (μm) |
| EXAMPLE 9 | 41.68613 | AlN | 1247 | 464 | 353 | 5 |
| EXAMPLE 10 | 41.68510 | AlN | 1260 | 464 | 352 | 6 |
| EXAMPLE 11 | 41.68955 | AlN | 538 | 465 | 348 | 2 |
| EXAMPLE 12 | 41.69029 | AlN | 541 | 465 | 350 | 2 |
| EXAMPLE 13 | 41.69071 | AlN | 639 | 465 | 349 | 2 |
| EXAMPLE 14 | 41.68935 | AlN | 953 | 464 | 350 | 2 |
| EXAMPLE 15 | 41.69268 | AlN | 1000 | 465 | 352 | 2 |
| EXAMPLE 16 | 41.70533 | AlN | 1133 | 465 | 352 | 4 |

What is claimed is:

1. A blue-light emitting aluminum nitride material, wherein an a-axis length of a lattice constant is 3.1112 [Å] or less.

2. A blue-light emitting aluminum nitride material, wherein the lattice volume is 41.743 [Å³] or less.

3. A blue-light emitting aluminum nitride material containing silicon and europium.

4. A blue-light emitting aluminum nitride material according to claim 3, wherein the content of the silicon falls within a range of more than 0.5 [wt %] to less than 4 [wt %] and the content of the europium falls within a range of more than 0.03 [wt %] to less than 0.8 [wt %].

5. A blue-light emitting aluminum nitride material according to claim 1, which emits blue light having a peak within a wavelength range of more than 450 [nm] to less than 500 [nm] by irradiation of an electromagnetic wave or an electron beam having a wavelength of 400 [nm] or less.

6. A blue-light emitting aluminum nitride material according to claim 3, which emits blue light having a peak within a wavelength range of more than 450 [nm] to less than 500 [nm] by irradiation of an electromagnetic wave or an electron beam having a wavelength of 400 [nm] or less.

7. A blue-light emitting aluminum nitride material according to claim 1, wherein the wavelength of excitation light providing a maximum luminescence intensity in air falls within the range of more than 340 [nm] to less than 370 [nm].

8. A blue-light emitting aluminum nitride material according to claim 3, wherein the wavelength of excitation light providing a maximum luminescence intensity in air falls within the range of more than 340 [nm] to less than 370 [nm].

9. A method of manufacturing the blue-light emitting aluminum nitride material according to claim 1, comprising the steps of:
adding carbon or a material capable of generating a carbon by thermal decomposition to the raw material;
reducing the prepared material in a nitrogen atmosphere at a temperature from more than 1400[° C.] to less than 1600[° C.]; and
firing the prepared material after the reducing step.

10. A method of manufacturing the blue-light emitting aluminum nitride material according to claim 3, comprising the steps of:
adding carbon or a material capable of generating a carbon by thermal decomposition to the raw material;
reducing the prepared material in a nitrogen atmosphere at a temperature from more than 1400[° C.] to less than 1600[° C.]; and
firing the prepared material after the reducing step.

11. A method of manufacturing the blue-light emitting aluminum nitride material according to claim 9, wherein, in the reducing step, the carbon or the material capable of generating a carbon by thermal decomposition is added not less than 1.0-fold by molar ratio relative to the amount of oxygen contained in the raw-material.

12. A method of manufacturing the blue-light emitting aluminum nitride material according to claim 10, wherein, in the reducing step, the carbon or the material capable of generating a carbon by thermal decomposition is added not less than 1.0-fold by molar ratio relative to the amount of oxygen contained in the raw-material.

13. A method of manufacturing a blue-light emitting aluminum nitride material according to claim 9, further comprising the steps of:
subjecting the blue-light emitting aluminum nitride material to a heat treatment process performed at 500[° C.] or more.

14. A method of manufacturing a blue-light emitting aluminum nitride material according to claim 10, further comprising the steps of:
subjecting the blue-light emitting aluminum nitride material to a heat treatment process performed at 500[° C.] or more.
